(19) United States
(12) Patent Application Publication
(10) Pub. No.: US 2026/0293564 A1
(43) Pub. Date: Sep. 24, 2026

(54) METHOD FOR MANUFACTURING SEMICONDUCTOR DEVICE

(71) Applicants: KABUSHIKI KAISHA TOSHIBA, Kawasaki-shi, Kanagawa (JP); Toshiba Electronic Devices & Storage Corporation, Kawasaki-shi, Kanagawa (JP)

(72) Inventors: Kentaro MORI, Fujisawa Kanagawa (JP); Kazushiro NOMURA, Kawasaki Kanagawa (JP); Kenichi OOHASHI, Kawasaki Kanagawa (JP)

(73) Assignees: KABUSHIKI KAISHA TOSHIBA, Kawasaki-shi, Kanagawa (JP); Toshiba Electronic Devices & Storage Corporation, Kawasaki-shi, Kanagawa (JP)

(21) Appl. No.: 19/475,782

(22) PCT Filed: Feb. 26, 2024
(86) PCT No.: PCT/JP2024/006781

§ 371 Date: Oct. 16, 2025

(30) Foreign Application Priority Data
Jul. 31, 2023 (JP) 2023-125147

(51) Int. Cl. H10P 54/94; H10P 54/92; H10P 72/70; H10W 46/00

(52) U.S. Cl. CPC H10P 54/94; H10P 54/922; H10P 72/7402; H10P 72/7416; H10W 46/301; H10W 46/501

(57) ABSTRACT

A method for manufacturing a semiconductor device according to an embodiment has a mark forming step, a first adhering step, a grinding step, and a processing step. The mark forming step is a step of forming recessed portions on a device surface on which a circuit pattern of a base material made of a semiconductor material is formed. The first adhering step is a step of adhering the device surface to a support substrate. The grinding step is a step of forming a grinding surface by grinding a surface of the base material on a side opposite to the device surface in a state of being supported by the support substrate. The processing step is a step of performing processing on the base material from the grinding surface side in a state of being supported by the support substrate. In the method for manufacturing the semiconductor device according to the embodiment, in the grinding step, the recessed portions are exposed on the grinding surface to serve as marks, and in the processing step, the processing is performed based on the marks.

### TECHNICAL FIELD

An embodiment of the present invention relates to a method for manufacturing a semiconductor device.

The present application claims priority based on Japanese Patent Application No. 2023-125147 filed on Jul. 31, 2023, the contents of which are incorporated herein by reference.

### BACKGROUND ART

Semiconductor devices such as metal oxide semiconductor field effect transistors (MOSFETs) are used for purposes of power conversion and the like. Such semiconductor devices are manufactured by forming a circuit pattern on a base material and then segmenting it into individual chips. Each of steps related to manufacturing of a semiconductor device is performed through positional alignment with alignment lines formed on a device surface. On the other hand, in terms of product quality, it may be preferable that steps to be performed after the circuit pattern is formed (for example, segmenting step) be performed from a side opposite to the device surface. In this case, there is a problem that the alignment lines on the device surface cannot be directly confirmed, making it difficult to positionally align the base material.

### CITATION LIST

### Patent Documents

Patent Document 1: Japanese Unexamined Patent Application, First Publication No. 2016-096265

### SUMMARY OF INVENTION

### Technical Problem

An object of the present invention is to provide a method for manufacturing a semiconductor device in which positional alignment of a base material during steps is facilitated.

### Solution to Problem

A method for manufacturing a semiconductor device according to an embodiment has a mark forming step, a first adhering step, a grinding step, and a processing step. The mark forming step is a step of forming recessed portions on a device surface on which a circuit pattern of a base material made of a semiconductor material is formed. The first adhering step is a step of adhering the device surface to a support substrate. The grinding step is a step of forming a grinding surface by grinding a surface of the base material on a side opposite to the device surface in a state of being supported by the support substrate. The processing step is a step of performing processing on the base material from the grinding surface side in a state of being supported by the support substrate. In the method for manufacturing the semiconductor device according to the embodiment, in the grinding step, the recessed portions are exposed on the grinding surface to serve as marks, and in the processing step, the processing is performed based on the marks.

### BRIEF DESCRIPTION OF DRAWINGS

FIG. 1 A schematic view of a semiconductor device according to a first embodiment.

FIG. 2 A flowchart showing a method for manufacturing the semiconductor device according to the first embodiment.

FIG. 3 A schematic view showing a device surface forming step according to the first embodiment.

FIG. 4 A schematic view showing a mark forming step according to the first embodiment.

FIG. 5 A schematic view showing a device surface in the mark forming step according to the first embodiment.

FIG. 6 A schematic view showing a first adhering step according to the first embodiment.

FIG. 7 A schematic view showing a grinding step according to the first embodiment.

FIG. 8 A schematic view showing a film formation step according to the first embodiment.

FIG. 9 An example of an enlarged view of a film portion in the vicinity of groove portions according to the first embodiment.

FIG. 10 Another example of an enlarged view of the film portion in the vicinity of the groove portions according to the first embodiment.

FIG. 11 Another example of an enlarged view of the film portion in the vicinity of the groove portions according to the first embodiment.

FIG. 12 A schematic view showing a photoresist coating step according to the first embodiment.

FIG. 13 A schematic view showing an exposing step according to the first embodiment.

FIG. 14 A schematic view of a photomask according to the first embodiment.

FIG. 15 A schematic view showing a development step according to the first embodiment.

FIG. 16 A schematic view showing an etching step according to the first embodiment.

FIG. 17 A schematic view of a photoresist removing step according to the first embodiment.

FIG. 18 A schematic view showing a segmenting step according to the first embodiment.

FIG. 19 A schematic view showing a second adhering step according to the first embodiment.

FIG. 20 A schematic view showing a support substrate detaching step according to the first embodiment.

FIG. 21 A schematic view showing a picking-up step according to the first embodiment.

FIG. 22 A schematic view showing the device surface in the mark forming step according to a modification example.

FIG. 23 A flowchart showing a method for manufacturing a semiconductor device according to a second embodiment.

FIG. 24 A schematic view showing a second adhering step according to the second embodiment.

FIG. 25 A schematic view showing a support substrate detaching step according to the second embodiment.

FIG. 26 A schematic view showing a segmenting step according to the second embodiment.

### DESCRIPTION OF EMBODIMENTS

Hereinafter, a method for manufacturing a semiconductor device and a semiconductor device according to an embodiment will be described with reference to the drawings.

In this specification, in order to indicate positional relationships of components and the like, the upward direction of the drawings will be described as “up”, and the downward direction of the drawings will be described as “down”. In this specification, the concepts of “up” and “down” are not necessarily terms indicating a relationship with the direction of gravity.

### First Embodiment

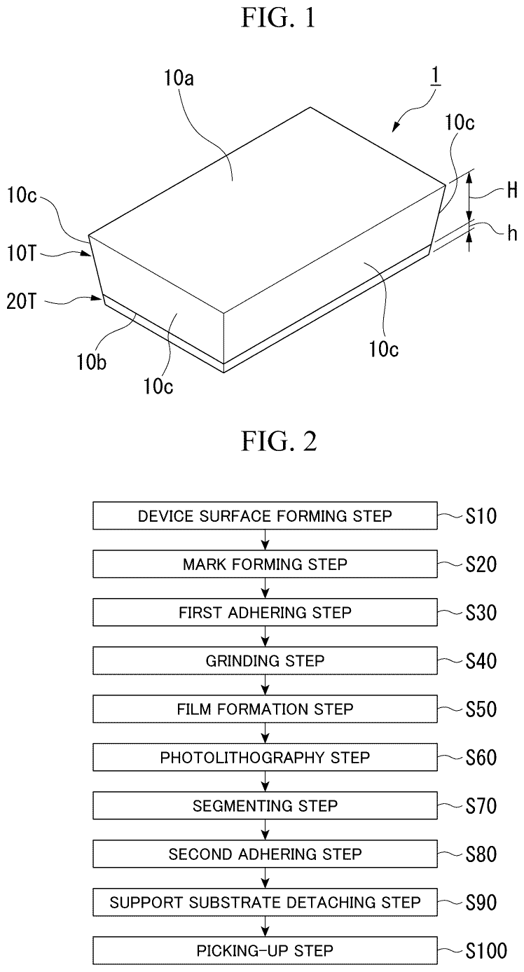

FIG. 1 is a schematic view of a semiconductor device 1 according to a first embodiment. For example, the semiconductor device 1 according to the present embodiment is a MOSFET, an insulated gate bipolar transistor (IGBT), or the like. The semiconductor device 1 according to the present embodiment includes a semiconductor chip 10T having a rectangular plate shape, and an electrode 20T provided on one surface of the semiconductor chip 10T.

The semiconductor chip 10T is made of a semiconductor material. In this specification, examples of the semiconductor material include silicon (Si), silicon carbide (SiC), gallium arsenide (GaAs), and gallium nitride (GaN), but it is not limited to these.

The semiconductor chip 10T has a device surface 10a, a rear surface 10b positioned on a side opposite to the device surface 10a, and four side surfaces 10c connecting the device surface 10a and the rear surface 10b. The area of each of the side surfaces 10c is sufficiently smaller than the areas of the device surface 10a and the rear surface 10b. A circuit pattern is formed on the device surface 10a. For example, a MOSFET device, an IGBT device, or the like is formed on the device surface 10a. In the following description, the distance dimension between the device surface 10a and the rear surface 10b will be referred to as a thickness H of the semiconductor chip 10T.

The electrode 20T is provided on the rear surface 10b of the semiconductor chip 10T. The electrode 20T comes into contact with the rear surface 10b of the semiconductor chip 10T. For example, when the semiconductor chip 10T is a MOSFET chip, the electrode 20T is a drain electrode of the MOSFET. The electrode 20T contains an electrically conductive material. Here, examples of the electrically conductive material include copper (Cu), aluminum (Al), nickel (Ni), silver (Ag), and gold (Au), but it is not limited to these.

In the semiconductor chip 10T according to the present embodiment, the area of the device surface 10a is larger than the area of the rear surface 10b. In addition, all the side surfaces 10c of the semiconductor chip 10T are inclined with respect to a normal line on the device surface 10a. All the side surfaces 10c are each inclined in a direction in which a side surface 10c approaches another side surface 10c side positioned on a side opposite thereto as it goes from the device surface 10a side toward the rear surface 10b side. At least one set of side surfaces 10c of the four side surfaces 10c facing each other on sides opposite thereto need only be inclined in a direction in which they approach each other as they go from the device surface 10a side toward the rear surface 10b side.

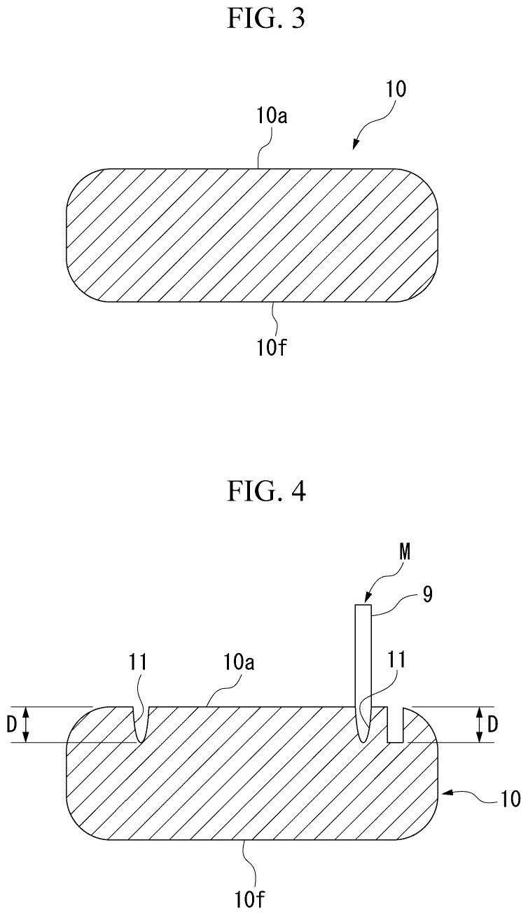

FIG. 2 is a flowchart showing a method for manufacturing the semiconductor device 1 according to the present embodiment. The method for manufacturing the semiconductor device 1 according to the present embodiment has a device surface forming step S10, a mark forming step S20, a first adhering step S30, a grinding step S40, a film formation step S50, a photolithography step (processing step) S60, a segmenting step (processing step) S70, a second adhering step S80, a support substrate detaching step S90, and a picking-up step S100.

FIG. 3 is a schematic view showing the device surface forming step S10 according to the present embodiment. The device surface forming step S10 is a step of forming a circuit pattern of a MOSFET device or an IGBT device on one surface of a disk-shaped base material 10 (semiconductor wafer) made of a semiconductor material, and making this surface into the device surface 10a, for example. In the following description, a surface on a side opposite to the device surface 10a before the grinding step S40 (which will be described below) is performed will be referred to as an initial rear surface 10f. Although they are not shown in the diagrams, the device surface forming step S10 and the mark forming step S20 performed thereafter are performed in a state of supporting the base material 10 on the initial rear surface 10f.

FIG. 4 is a schematic view showing the mark forming step S20 according to the present embodiment. The mark forming step S20 according to the present embodiment is a step of forming a plurality of groove portions (recessed portions, marks) 11 having a depth D and a plurality of hole portions (recessed portions, marks) 12 having the depth D on the device surface 10a by processing the device surface 10a of the base material 10.

In the present embodiment, the groove portions 11 function as marks in the subsequent segmenting step S70. On the other hand, the hole portions 12 function as marks in the subsequent photolithography step S60. The steps in which the groove portions 11 and the hole portions 12 in the present embodiment are used are merely examples and can be interchanged or replaced. Therefore, the hole portions 12 may be used as marks in the segmenting step S70, and the groove portions 11 may be used as marks in the photolithography step S60.

The depths D of the groove portions 11 and the hole portions 12 are larger than the thickness H of the semiconductor chip 10T (refer to FIG. 1) manufactured by the manufacturing method according to the present embodiment. In the present embodiment, the depths D of the groove portions 11 and the hole portions 12 coincide with each other. However, the depths D of the groove portions 11 and the hole portions 12 do not have to coincide with each other as long as they are larger than the thickness H. In addition, the shapes of the groove portions 11 and the hole portions 12 functioning as marks in the present embodiment are merely examples, and the marks are not limited to the shapes of the present embodiment as long as they are recessed portions processed in a depth direction from the device surface 10a. In this specification, the term “recessed portion” means a shape which is processed in the depth direction with respect to a predetermined surface (in the present embodiment, the device surface 10a), and is a concept which also includes a penetration portion penetrating it in the depth direction. Therefore, the recessed portions formed in the mark forming step S20 may penetrate the base material 10 in a thickness direction. In addition, the shapes of bottom portions of “the recessed portions” do not need to be flat and may be circular shapes as those of the groove portions 11, or any other shape may be adopted.

In the mark forming step S20 according to the present embodiment, the groove portions 11 are formed by a dicing device M used in segmentation processing (refer to the subsequent segmenting step S70). The groove portions 11 are formed using a disk-shaped rotary blade 9 provided in the dicing device M. In addition, a laser may be used for forming the groove portions 11.

According to the present embodiment, in the mark forming step S20, the hole portions 12 are formed using a laser, for example. In addition, a cutting tool such as a drill may also be used for forming the hole portions 12. The hole portions 12 according to the present embodiment are circular holes in a plan view. However, the shapes of the hole portions 12 are not limited.

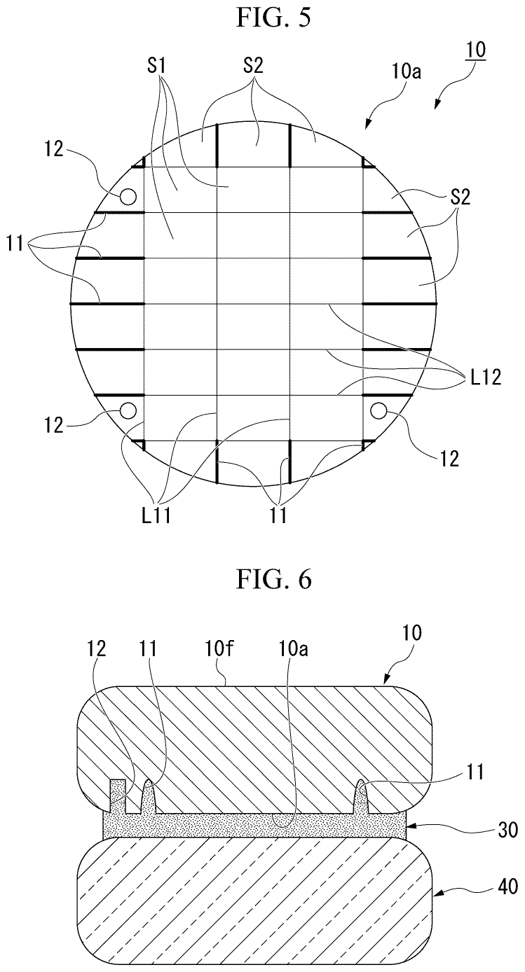

FIG. 5 is a schematic view showing the device surface 10a after the mark forming step S20. In FIG. 5, the groove portions 11 are indicated by bold lines. As shown in FIG. 5, a plurality of alignment lines L11 and L12 are formed in advance on the device surface 10a. The alignment lines L11 and L12 are used as reference positions for forming a circuit pattern in the device surface forming step S10. The plurality of alignment lines L11 and L12 include a plurality of first alignment lines L11 and a plurality of second alignment lines L12. The first alignment lines L11 and the second alignment lines L12 extend in directions orthogonal to each other. The alignment lines L11 and L12 divide the device surface 10a vertically and horizontally into a plurality of divisions.

The divisions disposed between the alignment lines L11 and L12 are classified into rectangular valid divisions S1 utilized as the semiconductor devices 1, and removal divisions S2 disposed along an outer edge of the device surface 10a. A circuit pattern for one semiconductor device 1 is individually formed in one valid division S1. On the other hand, no circuit pattern is formed in the removal divisions S2. The removal divisions S2 are disposed to surround the center region where the valid divisions S1 are concentrated.

In the present embodiment, the groove portions 11 and the hole portions 12 are formed based on the alignment lines L11 and L12. The groove portions 11 need only be provided at least one in order to detect the relative position on the device surface 10a when used as a mark, and it is more preferable to provide two or more groove portions in order to enhance the detection accuracy. The groove portions 11 according to the present embodiment are formed on the alignment lines L11 and L12 to overlap the portions dividing the removal divisions S2 adjacent to each other. That is, the groove portions 11 according to the present embodiment are formed in a manner of overlapping end portions of some alignment lines L11 and L12. The groove portions 11 according to the present embodiment are formed on all the alignment lines L11 and L12, of the plurality of alignment lines L11 and L12, dividing the removal divisions S2. However, the groove portions 11 need only be formed on the alignment lines L11 and L12 dividing at least some of the removal divisions S2.

The hole portions 12 according to the present embodiment are provided three on the device surface 10a. The hole portions 12 need only be provided at least two in order to detect the relative position on the device surface 10a when used as marks, and it is more preferable to provide three or more in order to enhance the detection accuracy. In addition, the plurality of hole portions 12 are preferably disposed separately within the device surface 10a in order to enhance the detection accuracy. The hole portions 12 according to the present embodiment are provided three on the device surface 10a and are disposed in the removal divisions S2 different from each other in the vicinity of the outer edge of the device surface 10a.

FIG. 6 is a schematic view showing the first adhering step S30 according to the present embodiment. During a process shifting from the mark forming step S20 to the first adhering step S30, the base material 10 is turned upside down. The first adhering step S30 is a step of adhering the device surface 10a facing downward to a support substrate 40 using an adhesive 30. By going through the first adhering step S30, the base material 10 is fixed to the support substrate 40.

In the first adhering step S30, first, the device surface 10a is coated with the uncured adhesive 30. Subsequently, the device surface 10a is caused to face a support surface of the support substrate 40, and they are adhered together. Subsequently, the adhesive 30 is cured. Regarding the adhesive 30, for example, an acryl-based adhesive, an epoxy-based adhesive, or a silicon-based adhesive can be preferably used. In addition, for example, the support substrate 40 is glass, or a plate-shaped member made of silicon (Si).

FIG. 6 shows a case in which the insides of the groove portions 11 and the hole portions 12 are completely filled with the adhesive 30. However, the filling state of the adhesive 30 is not limited to the state shown in FIG. 6. That is, the adhesive 30 may fill the groove portions 11 and the hole portions 12 partway, and voids may be provided in the vicinity of bottom portions of the groove portions 11 and the hole portions 12. In addition, the groove portions 11 and the hole portions 12 do not have to be filled with the adhesive 30.

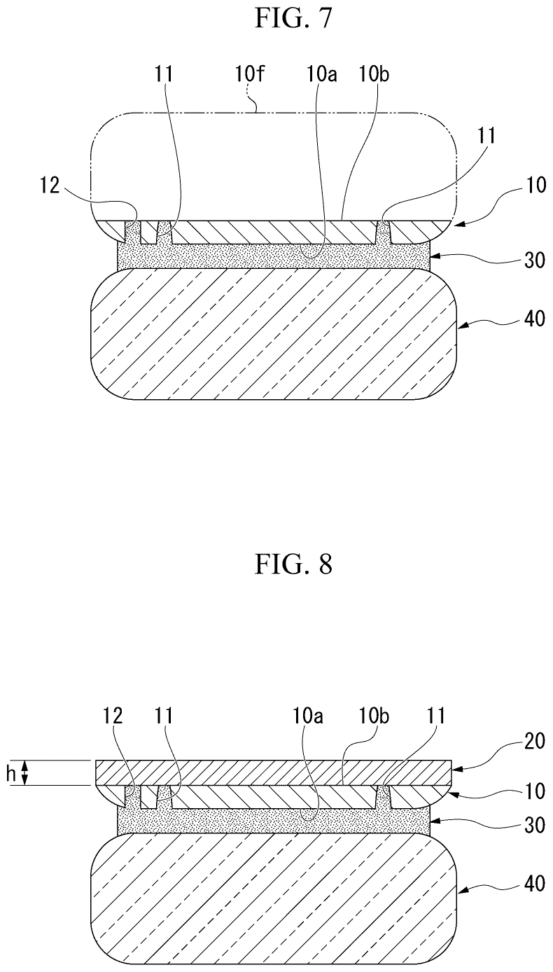

FIG. 7 is a schematic view showing the grinding step S40 according to the present embodiment. The grinding step S40 is a step of grinding the initial rear surface 10f to form a rear surface (grinding surface) 10b. The grinding step S40 according to the present embodiment is performed in a state in which the base material 10 is supported by the support substrate 40. Through the grinding step S40, the base material 10 has the thickness H. Accordingly, the groove portions 11 and the hole portions 12 formed from the device surface 10a side are connected to the rear surface 10b side, and the groove portions 11 and the hole portions 12 penetrate the base material 10. That is, in the method for manufacturing the semiconductor device 1 according to the present embodiment, in the grinding step S40, the groove portions 11 and the hole portions 12 are exposed on the rear surface 10b to serve as marks which can be confirmed from the rear surface 10b side. In addition, as described above, the insides of the groove portions 11 and the hole portions 12 according to the present embodiment are filled with the adhesive 30. For this reason, since the groove portions 11 penetrate the base material 10, the adhesive 30 is exposed from the rear surface 10b.

FIG. 8 is a schematic view showing the film formation step S50 according to the present embodiment. The film formation step S50 is a step of forming a film portion 20 on the rear surface 10b of the base material 10. The film formation step S50 according to the present embodiment is performed in a state in which the base material 10 is supported by the support substrate 40. The film portion 20 according to the present embodiment is a metal film made of a metal material. However, the material of the film portion 20 is not limited. According to the present embodiment, for example, the film formation step S50 is performed by chemical vapor deposition (CVD), physical vapor deposition (PVD), electrolytic plating, electroless plating, or the like. According to the present embodiment, a thickness h of the film portion 20 is approximately 40 μm, for example. However, the thickness h of the film portion 20 not limited to that of the present embodiment.

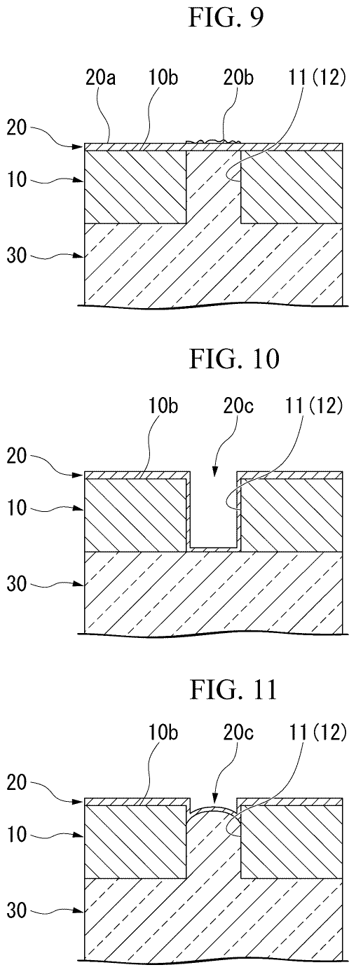

As described above, the adhesive 30 inside the groove portions 11 and the hole portions 12 is exposed on the rear surface 10b. For this reason, a part of the film portion 20 is subjected to film formation on the adhesive 30. FIG. 9 is an enlarged view of the film portion 20 in the vicinity of the groove portions 11 (or the hole portions 12). In the film portion 20, when the material on a film formation target surface differs, the film portion 20 of the portion is in a state different from that of other portions. For example, a region 20b of the film portion 20 subjected to film formation on the adhesive 30 has observable differences, such as local unevenness, coarse surface roughness, or a smaller or larger film thickness, compared to a region 20a subjected to film formation on the base material 10. For this reason, even after the film portion 20 is formed on the rear surface 10b, the positions of the groove portions 11 and the hole portions 12 can be ascertained by observing the film portion 20. FIG. 9 shows a case in which the insides of the groove portions 11 and the hole portions 12 are completely filled with the adhesive 30. However, the adhesive 30 inside the groove portions 11 and the hole portions 12 may not fill the groove portions 11 and the hole portions 12 as shown in FIG. 10, or may fill only a part of the groove portions 11 and the hole portions 12 as shown in FIG. 11. In these cases, since a recessed shape 20c is formed on a surface of the film portion 20, it is easy to ascertain the positions of the groove portions 11 and the hole portions 12 by observing the film portion 20.

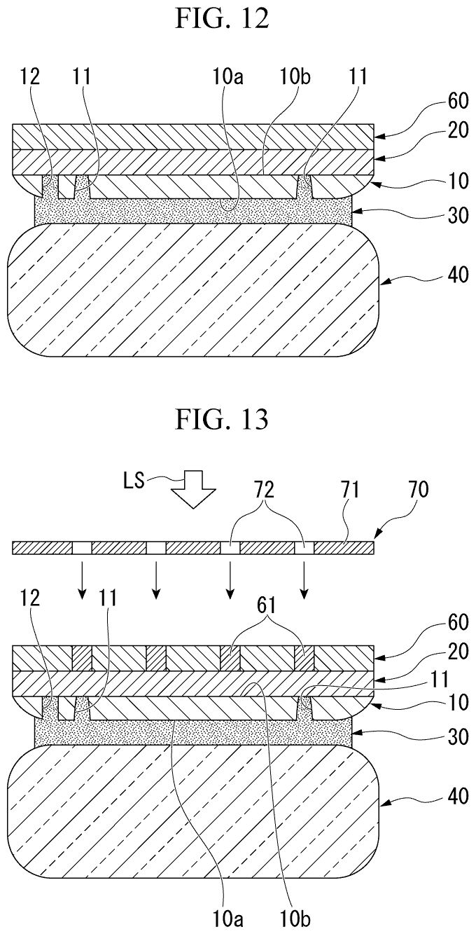

FIGS. 12 to 17 are schematic views showing the photolithography step S60 according to the present embodiment. The photolithography step S60 is a step of performing etching processing of the film portion 20 subjected to film formation in the film formation step S50 into a desired pattern. The photolithography step S60 has a photoresist coating step, an exposing step, a development step, an etching step, and a photoresist removing step.

FIG. 12 is a schematic view showing the photoresist coating step according to the present embodiment. In the photoresist coating step, the surface of the film portion 20 is coated with a photoresist 60 by means such as spin coating and is cured after pre-baking processing.

FIG. 13 is a schematic view showing the exposing step according to the present embodiment. In the exposing step, the photoresist 60 is irradiated with light of a light source LS through a photomask 70. In the exposing step, a part of light which has been transmitted through the photomask 70 reaches the photoresist 60. The portion of the photoresist 60 where light has reached becomes a photosensitive portion 61 and whose solubility changes. In the present embodiment, the photosensitive portion 61 is formed into a line shape in a manner of overlapping the alignment lines L11 and L12 (refer to FIG. 5). There is a need for the position of the photosensitive portion 61 to be positionally set with respect to the base material 10. For this reason, there is a need for the photomask 70 to be positionally aligned such that a light transmission portion 72 is disposed at a desired position with respect to the base material 10.

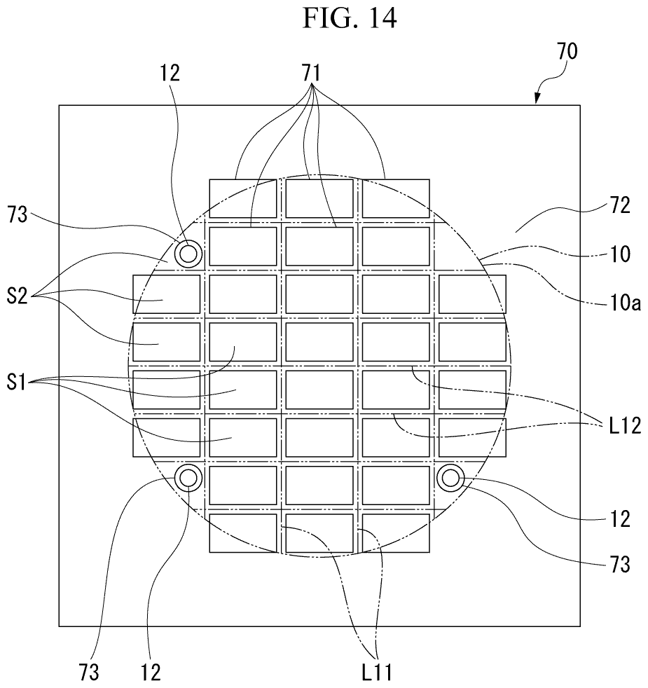

FIG. 14 is a schematic view of the photomask 70 according to the present embodiment. The photomask 70 is provided with a plurality of mask portions 71 limiting transmission of light, and the light transmission portion 72 positioned at portions other than the mask portions 71 and transmitting light. The light transmission portion 72 is formed into a line shape such that the portions overlapping the alignment lines L11 and L12 are exposed to light.

The photomask 70 is provided with three alignment marks 73 for positionally aligning the photomask 70 with respect to the base material 10. In the exposing step, by causing the three alignment marks 73 to respectively overlap the hole portions 12 exposed on the rear surface 10b of the base material 10, the photomask 70 can be positionally aligned with respect to the base material 10. That is, in the exposing step, the photomask 70 is positionally aligned based on the hole portions 12. The method for positionally aligning the photomask 70 and the base material 10 described herein is merely an example, and other methods may be adopted as long as they can be performed based on the hole portions 12.

The photolithography step S60 according to the present embodiment is performed from the rear surface 10b side of the base material 10. For this reason, it is difficult to positionally align the photomask 70 using the alignment lines L11 and L12 provided on the device surface 10a. In the present embodiment, the hole portions 12 provided on the device surface 10a penetrate the rear surface 10b side. For this reason, in the photolithography step S60, the positions of the hole portions 12 can be ascertained from the rear surface 10b side through the film portion 20. The photomask 70 is positionally aligned by observing the film portion 20, ascertaining the positions of the hole portions 12, and causing them to overlap the alignment marks 73 of the photomask 70. That is, the photolithography step S60 according to the present embodiment is performed based on the hole portions 12 penetrating the rear surface 10b side.

In the present embodiment, a case in which the photomask 70 is positionally aligned using the hole portions 12 has been described. However, the photomask 70 can also be positionally aligned using the groove portions 11. In this case, the photomask 70 is provided with the alignment marks 73 to overlap the groove portions 11. In addition, in this case, the hole portions 12 of the base material 10 are omitted.

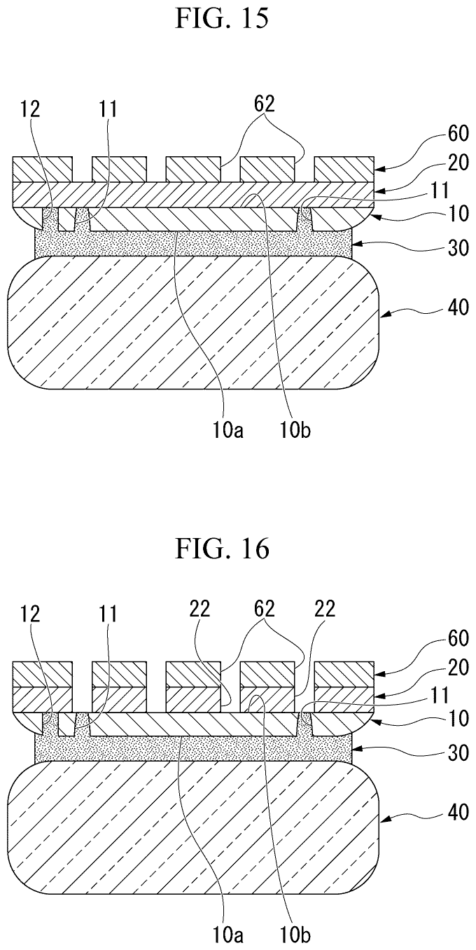

FIG. 15 is a schematic view showing the development step according to the present embodiment. The development step is a step of performing post-baking by dissolving and removing the photosensitive portion 61 of the photoresist 60 using a developing solution. By removing the photosensitive portion 61, opening portions 62 are formed in the photoresist 60. In addition, a part of the film portion 20 is exposed through the opening portions 62. In the present embodiment, the photolithography step S60 using a positive-type photoresist 60 will be described. However, the photolithography step may be performed using a negative-type photoresist. When the negative-type photoresist is used, portions other than the photosensitive portion dissolve and form the opening portions.

FIG. 16 is a schematic view showing the etching step according to the present embodiment. The etching step is a step of removing the film portion 20 exposed through the opening portions 62 of the photoresist 60 by etching. As described above, the light transmission portion 72 of the photomask 70 according to the present embodiment (FIG. 14) is formed into a line shape in a manner of overlapping the alignment lines L11 and L12. For this reason, by going through the etching step, recessed grooves 22 overlapping the alignment lines L11 and L12 are formed in the film portion 20. The recessed grooves 22 penetrate the film portion 20 in the thickness direction. Therefore, the rear surface 10b of the base material 10 is exposed to bottom portions of the recessed grooves 22.

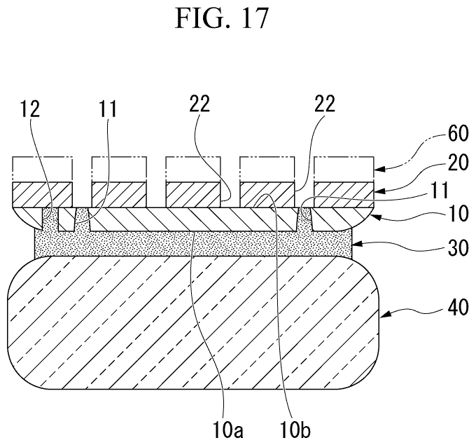

FIG. 17 is a schematic view of the photoresist removing step according to the present embodiment. In the photoresist removing step, the photoresist 60 is removed, and the surface of the film portion 20 is exposed.

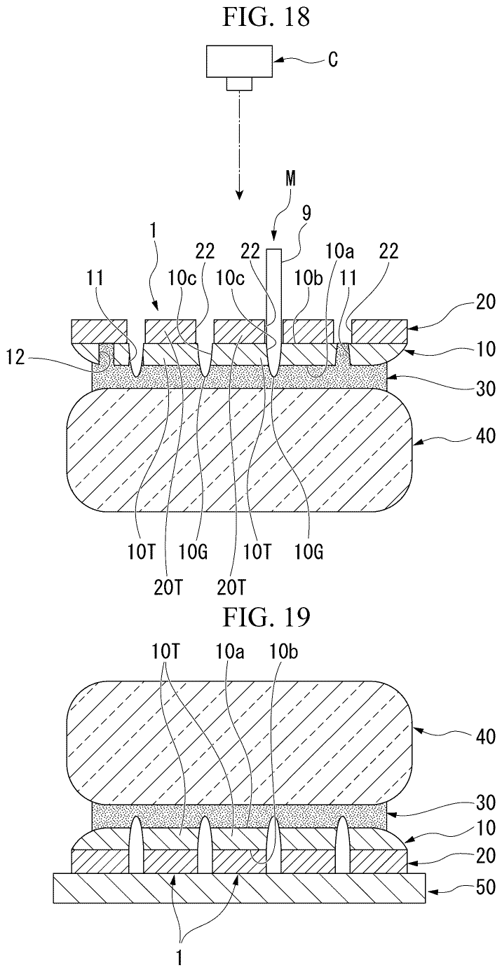

FIG. 18 is a schematic view showing the segmenting step S70 according to the present embodiment. The segmenting step S70 is a step of segmenting the base material 10 by cutting the base material 10 and taking out the semiconductor chip 10T. The segmenting step S70 according to the present embodiment is performed in a state in which the base material 10 is supported by the support substrate 40.

In the segmenting step S70 according to the present embodiment, the base material 10 is cut by the dicing device M using the blade 9. In addition, a laser dicing device may be used for cutting the base material 10.

The segmenting step S70 according to the present embodiment is performed from the rear surface 10b side of the base material 10. For this reason, in the segmenting step S70, it is difficult to observe the alignment lines L11 and L12 provided on the device surface 10a (refer to FIG. 5) from the processing side. In addition, the film portion 20 according to the present embodiment is provided with the recessed grooves 22 extending along the alignment lines L11 and L12. For this reason, the base material 10 can also be segmented by cutting the base material 10 along the recessed grooves 22. However, the recessed grooves 22 are formed sufficiently wide with respect to the alignment lines L11 and L12 in order to avoid contact of inner side surfaces of the recessed grooves 22 with the blade 9 when the base material 10 is cut. In addition, since the recessed grooves 22 are formed by etching, the positional accuracy is low. For this reason, when the segmenting step S70 is performed based on the recessed grooves 22, there is a problem that the positional accuracy on cutting surfaces in the segmenting step S70 is unlikely to be enhanced.

In the present embodiment, the groove portions 11 provided on the device surface 10a penetrate the rear surface 10b side. For this reason, in the segmenting step S70, the positions of the groove portions 11 can be ascertained from the rear surface 10b side. The dicing device M has an image capturing device C for observing the groove portions 11 from above. The dicing device M ascertains the positions of the groove portions 11 using the image capturing device C and cuts the base material 10 based on the groove portions 11. That is, the segmenting step S70 according to the present embodiment is performed based on the groove portions 11 penetrating the rear surface 10b side.

As shown in FIG. 5, all the alignment lines L11 and L12 according to the present embodiment are disposed on extended lines of the groove portions 11. Therefore, the dicing device M segments the base material 10 by cutting the base material 10 in a straight line shape along the groove portions 11 ascertained by the image capturing device C. By cutting the base material 10, the semiconductor device 1 provided with the electrode 20T on the rear surface 10b side of the semiconductor chip 10T is formed.

As shown in FIG. 18, in the segmenting step S70, the dicing grooves 10G are formed in the base material 10 using the blade 9. Even when the blade 9 has a uniform thickness, the width dimension of the dicing grooves 10G gradually increases as it goes toward the opening side from the bottom portion. This is because cutting surfaces are polished by the side surfaces of the blade 9 on the opening side of the dicing grooves 10G. Therefore, the cutting surfaces of the base material 10 facing each other with the dicing grooves 10G sandwiched therebetween are gradually separated toward the opening side. For this reason, the pair of side surfaces 10c of the semiconductor chip 10T formed between the cutting surfaces are inclined in a direction in which they gradually approach each other as they go from the device surface 10a side toward the rear surface 10b side.

FIG. 19 is a schematic view showing the second adhering step S80 according to the present embodiment. During a process shifting from the segmenting step S70 to the second adhering step S80, the base material 10 is turned upside down. The second adhering step S80 is performed in a state of being supported by the support substrate 40. The second adhering step S80 is a step of adhering the base material 10 to a dicing tape 50 on a side opposite to the support substrate 40. In the present embodiment, since the film portion 20 is provided on the rear surface 10b side of the base material 10, the base material 10 is adhered to the dicing tape 50 with the film portion 20 therebetween.

FIG. 20 is a schematic view showing the support substrate detaching step S90 according to the present embodiment. The support substrate detaching step S90 is a step of detaching the support substrate 40 from the base material 10. In the support substrate detaching step S90 according to the present embodiment, the adhesive 30 may be melted using a solvent, or the adhesive strength thereof may be weakened by irradiating it with a laser through the light-transmitting support substrate 40. Moreover, the support substrate detaching step S90 may be a step of detaching the support substrate 40 from the base material 10 by mechanical peeling in which a sharp tool is inserted between the base material 10 and the support substrate 40 to peel off the adhesive 30.

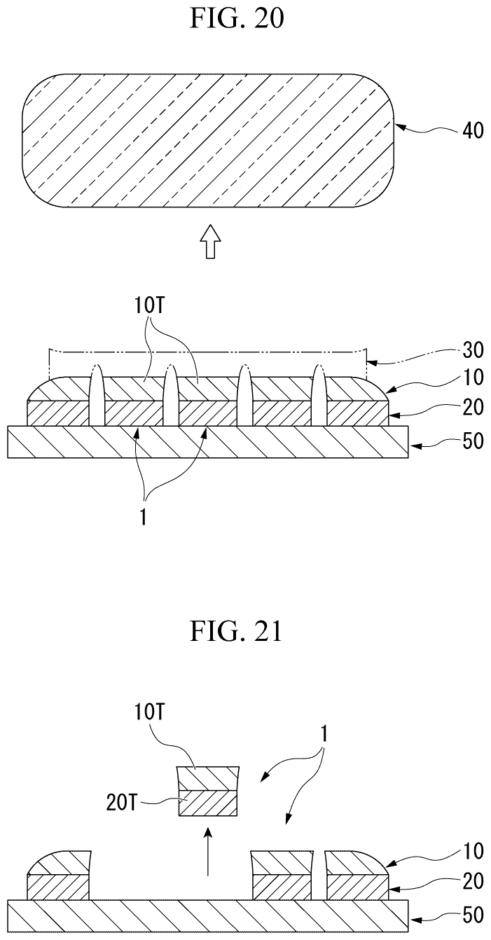

FIG. 21 is a schematic view showing the picking-up step S100 according to the present embodiment. The picking-up step S100 is a step of individually taking out the segmented semiconductor device 1 on the dicing tape 50 from the dicing tape 50. In the picking-up step S100, first, processing of weakening the adhesive strength of the adhesive layer on the surface of the dicing tape 50 is performed. Regarding the processing of weakening the adhesive strength of the adhesive layer on the dicing tape 50, for example, a step of irradiating the adhesive layer with ultraviolet rays or heating the adhesive layer is performed. In addition, in the picking-up step S100, the semiconductor device 1 is picked up by pushing one semiconductor device 1 upward with a pin from below the dicing tape 50, applying a negative pressure to the device surface 10a of the semiconductor device 1 and adsorbing it. By going through the foregoing steps, the semiconductor device 1 can be manufactured.

Next, operational effects according to the first embodiment will be described.

As shown in FIG. 2, the method for manufacturing the semiconductor device 1 according to the present embodiment has the mark forming step S20, the first adhering step S30, the grinding step S40, and the processing step (photolithography step S60 or segmenting step S70). As shown in FIG. 4, the mark forming step S20 is a step of forming recessed portions (groove portions 11 and hole portions 12) on the device surface 10a on which the circuit pattern of the base material 10 made of a semiconductor material is formed. As shown in FIG. 6, the first adhering step S30 is a step of adhering the device surface 10a to the support substrate 40. As shown in FIG. 7, the grinding step S40 is a step of grinding the surface of the base material 10 (initial rear surface 10f) on a side opposite to the device surface 10a in a state of being supported by the support substrate 40 to form the rear surface (grinding surface) 10b. As shown in FIGS. 12 to 18, the processing step (photolithography step S60 or segmenting step S70) is a step of performing processing on the base material 10 from the rear surface 10b side in a state of being supported by the support substrate 40. In the method for manufacturing the semiconductor device 1 according to the present embodiment, in the grinding step S40, the recessed portions (groove portions 11 and hole portions 12) are exposed on the rear surface 10b to serve as marks. In the method for manufacturing the semiconductor device 1 according to the present embodiment, in the processing step (photolithography step S60 or segmenting step S70), processing is performed based on the marks (groove portions 11 and the hole portions 12).

According to this constitution, in the mark forming step S20, the recessed portions (groove portions 11 and hole portions 12) can be formed from the device surface 10a side based on the alignment lines L11 and L12 or the like on the device surface 10a. In addition, the formed recessed portions (groove portions 11 and hole portions 12) can be exposed from the rear surface 10b through the grinding step S40. Accordingly, when the processing step (photolithography step S60 or segmenting step S70) is performed from the rear surface 10b, it can be performed through positional alignment from the rear surface 10b side based on the recessed portions (groove portions 11 and hole portions 12). According to this constitution, in the processing step (photolithography step) which needs to be performed from the rear surface 10b side, it is easy to positionally align the base material 10 during processing. In addition, when a processing step requiring positional alignment of the base material 10 is performed, there is no need to turn the device surface 10a side upward for positional alignment, and therefore manufacturing steps can be simplified.

As shown in FIG. 18, in the method for manufacturing the semiconductor device 1 according to the present embodiment, the processing step is the segmenting step S70 of segmenting the base material 10 by cutting the base material 10 based on the mark (groove portions 11) in a state of being supported by the support substrate 40.

According to this constitution, regarding the processing step, the segmenting step S70 is performed from the rear surface 10b side in a state of being supported by the support substrate 40. In the related art, in the method for manufacturing a semiconductor device, the step of forming the semiconductor device 1 by cutting and segmenting a base material has been performed in a state of being mounted on a dicing tape. Since the dicing tape 50 has elasticity, if the base material is cut on the dicing tape, there has been a problem in that the base material is unlikely to be made stable and damage is likely to occur on cutting surfaces at the time of cutting. In contrast, according to the constitutions described above, the base material 10 is segmented in a state of being supported by the support substrate 40. For this reason, compared to when the base material 10 is segmented on the dicing tape 50, the base material 10 can be cut in a state of stably supporting the base material 10. Consequently, damage is unlikely to remain on the cutting surfaces after going through the segmenting step S70, and therefore the semiconductor device 1 with improved quality can be provided.

In addition, according to the constitutions described above, the segmenting step S70 is performed in a state in which the device surface 10a is adhered to the support substrate 40. Generally, in the segmenting step S70, particles are likely to be generated at the time of cutting, and these particles may be dispersed in a processing space and contaminate the device surface 10a. Particularly, when the segmenting step S70 is performed on the dicing tape 50, there is concern that a part of the dicing tape 50 may be scraped off by the blade 9 performing the segmenting step S70 and adhered to the device surface 10a, making it difficult to remove. According to the constitutions described above, since the device surface 10a is covered by the support substrate 40 with the adhesive 30 therebetween, adhesion of particles generated in the segmenting step S70 to the device surface 10a can be curbed, and therefore the semiconductor device 1 with improved quality can be provided.

In addition, according to the constitutions described above, after the segmenting step S70 is completed, the segmented base materials 10 (semiconductor chips 10T) are in a state of being mounted on the support substrate 40. For this reason, when processing (for example, etching of the side surfaces 10c) is performed with respect to the semiconductor chip 10T after the segmenting step S70, processing can be collectively performed with respect to a plurality of semiconductor chips 10T on the support substrate 40. In contrast, when the segmenting step S70 is performed on the dicing tape 50 as in the related art, in consideration of damage to the dicing tape 50, processing such as etching cannot be performed on the dicing tape 50. For this reason, in the manufacturing method in the related art, there is a need to perform the processing after the segmented semiconductor chips 10T are moved from the dicing tape 50 to a support table. According to the constitutions described above, when processing such as etching is performed with respect to the segmented semiconductor chips 10T, a step of remounting the semiconductor chips 10T on the support table can be omitted, and therefore manufacturing steps can be simplified.

As shown in FIG. 5, in the method for manufacturing the semiconductor device 1 according to the present embodiment, the device surface 10a is provided with the alignment lines L11 and L12 dividing the base material 10. At least some of the recessed portions are the groove portions 11 overlapping the alignment lines L11 and L12 when viewed in the thickness direction of the base material 10.

According to this constitution, by causing the recessed portions serving as marks to be the groove portions 11, the base material 10 can be positionally aligned by providing at least one groove portion 11. In addition, by disposing the groove portions 11 in a manner of overlapping the alignment lines L11 and L12 when viewed in the thickness direction of the base material 10, the segmenting step S70 can be performed by performing cutting along the groove portions 11. That is, it is easy to positionally align the cutting lines in the segmenting step S70, and therefore the semiconductor device 1 in which the positional accuracy of the cutting lines are enhanced can be manufactured.

In the method for manufacturing the semiconductor device 1 according to the present embodiment, the base material 10 is divided by the alignment lines L11 and L12 into a plurality of valid divisions S1 divided in a rectangular shape and a plurality of removal divisions S2 disposed along the outer edge. The groove portions 11 overlap parts of the alignment lines L11 and L12 dividing the removal divisions S2.

According to this constitution, a situation in which the cutting surfaces of the groove portions 11 formed in the mark forming step S20 constitute the outer side surface of the semiconductor device 1 as a final product can be avoided. For this reason, in the mark forming step S20, means for forming the groove portions 11 and various conditions for forming them can be set with a priority given to the processing speed over the state of the cutting surfaces so that the time required for the mark forming step S20 can be shortened. Consequently, while the surface accuracy on the side surfaces 10c of the manufactured semiconductor device 1 is maintained, the manufacturing time of the semiconductor device 1 can be shortened.

As shown in FIG. 2, the method for manufacturing the semiconductor device 1 according to the present embodiment has the film formation step S50 performed after the grinding step S40. The film formation step S50 is a step of forming the film portion 20 on the rear surface 10b. As shown in FIGS. 12 to 17, the processing step is the photolithography step S60 of etching and removing a part of the film portion 20 based on the marks (hole portions 12).

According to this constitution, regarding the processing step, the photolithography step S60 of etching a part of the film portion 20 can be performed. That is, the photomask 70 can be positionally aligned from the rear surface 10b side in the photolithography step S60. For this reason, the positional alignment accuracy of the photomask 70 can be enhanced, and therefore the recessed grooves 22 with high positional accuracy can be formed in the film portion 20.

As shown in FIG. 14, in the method for manufacturing the semiconductor device 1 according to the present embodiment, the device surface 10a is provided with the alignment lines L11 and L12 dividing the base material 10. In the photolithography step S60, the regions (recessed grooves 22) where the film portion 20 is etched overlap the alignment lines L11 and L12 when viewed in the thickness direction of the base material 10.

According to this constitution, the film portion 20 can be segmented through the photolithography step S60 in the size of the electrode 20T of the semiconductor device 1. Accordingly, there is no need to cut the film portion 20 in the segmenting step S70 performed separately. When the film portion 20 is sufficiently thick (40 μm or larger), if it is attempted to cut the film portion 20 and the base material 10 at the same time, a significant burden is applied to the base material 10, which will cause damage to the base material 10. Particularly, since the base material 10 is constituted using a brittle material such as silicon (Si) or silicon carbide (SiC), there is concern that cracking will occur in the base material 10 when it is cut at the same time with the film portion 20 below the film portion 20 which is made of a sufficiently thick ductile material. By segmenting the film portion 20 in the photolithography step S60, damage to the base material 10 when the base material 10 is cut can be curbed.

As shown in FIG. 2, the method for manufacturing the semiconductor device 1 according to the present embodiment has the segmenting step S70 performed after the photolithography step S60. The segmenting step S70 is a step of segmenting the base material 10 by cutting the base material 10.

When the film portion 20 is mechanically cut using the blade 9 or the like, burrs may be generated from the film portion 20. Since there is concern that the burrs generated from the film portion 20 affect the subsequent steps, another step is required to process the burrs. According to the constitutions described above, the film portion 20 are segmented in advance in the photolithography step S60 so that no burrs are generated from the film portion 20 in the segmenting step S70. For this reason, the segmenting step S70 can be smoothly performed.

As shown in FIG. 1, the semiconductor device 1 according to the present embodiment is made of a semiconductor material includes a plate-shaped semiconductor chip 10T. The semiconductor chip 10T has the device surface 10a, the rear surface 10b, and the four side surfaces 10c. A circuit pattern is formed on the device surface 10a. The rear surface 10b is positioned on a side opposite to the device surface 10a. The four side surfaces 10c connect the device surface 10a and the rear surface 10b. At least one set of the side surfaces 10c of the four side surfaces 10c facing each other on sides opposite thereto is inclined in a direction in which they approach each other as they go from the device surface 10a side toward the rear surface 10b side.

By performing the segmenting step S70 from the rear surface 10b side of the base material 10 using the blade 9, the side surfaces 10c have shapes inclined in a direction in which they approach each other as they go from the device surface 10a side toward the rear surface 10b side. That is, by having such side surfaces 10c, the manufacturing method described above can be employed, and therefore the semiconductor device 1 with improved quality can be provided.

A modification example which can be employed in the present embodiment will be described.

In the present embodiment, a case in which the film portion 20 is subjected to film formation on the rear surface 10b of the base material 10 in the film formation step S50 and a part of the film portion 20 is etched in the photolithography step S60 has been described. However, the semiconductor device 1 does not have to have the electrode 20T. In this case, in the method for manufacturing the semiconductor device 1, the film formation step S50 and the photolithography step S60 are omitted.

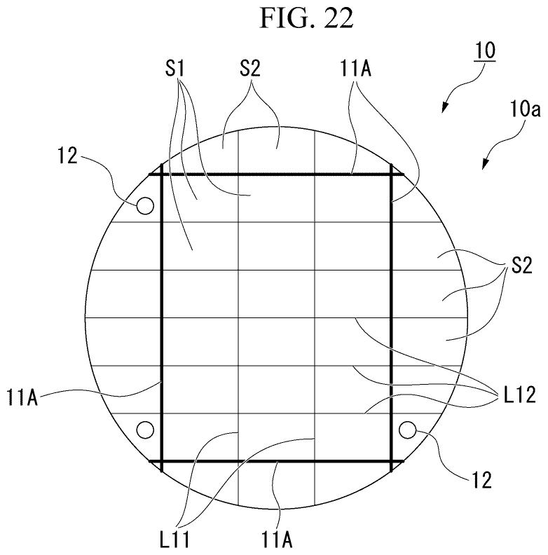

In the present embodiment, as shown in FIG. 5, the groove portions 11 are disposed only between the removal divisions S2 and are not disposed between the valid divisions S. For this reason, in the present embodiment, the cutting surfaces of the groove portions 11 serving as marks do not appear on the side surfaces 10c of the semiconductor device 1 as a final product. However, as in the modification example shown in FIG. 22, groove portions 11A may be disposed on the alignment lines L11 and L12 between the valid divisions S1 and the removal divisions S2. That is, the groove portions 11A may overlap the portions of the alignment lines L11 and L12 dividing the valid divisions S1. According to the present modification example, the cutting surfaces of the groove portions 11A formed in the mark forming step S20 can be utilized as the outer side surface of the semiconductor device 1 as a final product. For this reason, in the segmenting step S70, a part of the cutting step can be omitted so that the time required for the segmenting step S70 can be shortened. The groove portions 11A may be disposed between the valid divisions S1.

Next, the segmenting step S70 when forming the groove portions 11A according to the modification example will be described based on FIG. 22. The segmenting step S70 has a first cutting step of cutting the base material 10 in a direction along the first alignment lines L11, and a second cutting step of cutting the base material 10 in a direction along the second alignment lines L12.

In the first cutting step, first, the base material 10 is cut along one groove portion 11A overlapping the first alignment lines L11. Subsequently, the blade 9 is offset at a predetermined distance in a direction orthogonal to the first alignment lines L11, and the base material 10 is cut. Moreover, the base material 10 can be cut along all the first alignment lines L11 by repeating the procedure of cutting the base material 10 after the blade 9 is offset by a predetermined distance.

In the second cutting step, through a procedure similar to that of the first cutting step, the base material 10 is cut along the second alignment lines L12. That is, first, the base material 10 is cut along one groove portion 11A overlapping the second alignment lines L12. Subsequently, the blade 9 is offset at a predetermined distance in a direction orthogonal to the second alignment lines L12, and the base material 10 is cut. Moreover, the base material 10 can be cut along all the second alignment lines L12 by repeating the procedure of cutting the base material 10 after the blade 9 is offset by a predetermined distance. By going through the foregoing steps, the base material 10 is cut along all the alignment lines L11 and L12, and all the semiconductor chips 10T are taken out from the base material 10.

### Second Embodiment

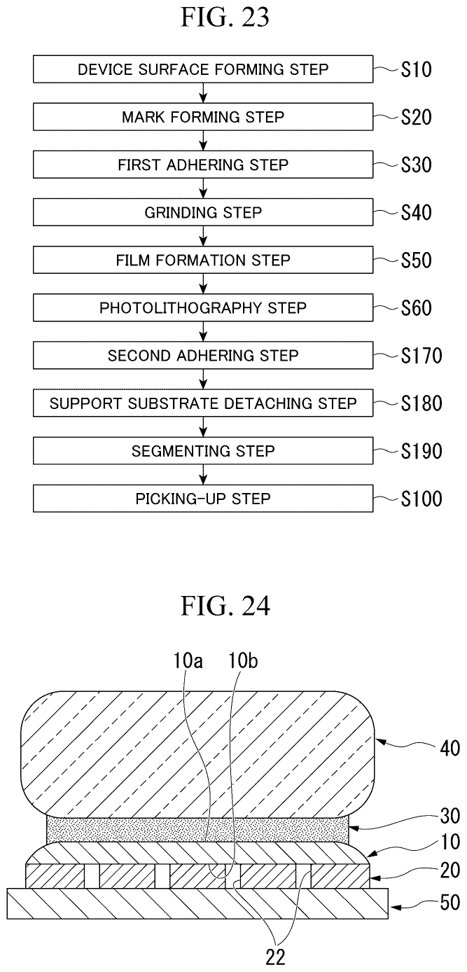

FIG. 23 is a flowchart showing a method for manufacturing the semiconductor device 1 according to a second embodiment. In description of the embodiments which will be described below, the same reference signs are applied to constituent elements having the same form as the embodiment which has already been described, and description thereof will be omitted.

The method for manufacturing the semiconductor device 1 according to the present embodiment has the device surface forming step S10, the mark forming step S20, the first adhering step S30, the grinding step S40, the film formation step S50, the photolithography step S60, a second adhering step S170, a support substrate detaching step S180, a segmenting step S190, and the picking-up step S100. The method for manufacturing the semiconductor device 1 according to the second embodiment differs from that of the first embodiment in the order of the second adhering step S170, the support substrate detaching step S180, and the segmenting step S190. In the second embodiment, description of each of the steps performed before the second adhering step S170 will be omitted.

FIG. 24 is a schematic view showing the second adhering step S170 according to the present embodiment. The second adhering step S170 is performed in a state of being supported by the support substrate 40. The second adhering step S170 is a step of adhering a surface on the film portion 20 side to the dicing tape 50. In the present embodiment, the second adhering step S170 is performed immediately after the photolithography step S60 and before the segmenting step S190. For this reason, the film portion 20 is segmented into a plurality of electrodes 20T in the stage of the second adhering step S170, and the base material 10 is not segmented.

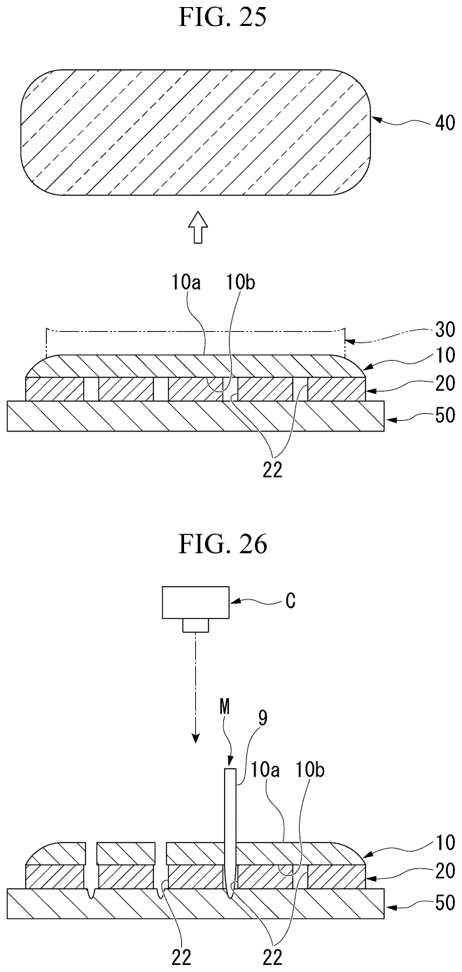

FIG. 25 is a schematic view showing the support substrate detaching step S180 according to the present embodiment. The support substrate detaching step S180 is a step of detaching the support substrate 40 from the base material 10. The support substrate detaching step S180 according to the present embodiment is performed through a procedure similar to that of the first embodiment.

FIG. 26 is a schematic view showing the segmenting step S190 according to the present embodiment. The segmenting step S190 according to the present embodiment is performed a state in which a surface on the film portion 20 side is adhered to the dicing tape 50. The base material 10 is cut by the dicing device M using the blade 9. The segmenting step S190 according to the present embodiment is performed from the device surface 10a side of the base material 10. For this reason, the dicing device M cuts the base material 10 along the alignment lines L11 and L12 using the image capturing device C. In the segmenting step S190 according to the present embodiment, since the film portion 20 has been segmented in advance, the blade 9 cuts only the base material 10.

Next, operational effects according to the second embodiment will be described.

The method for manufacturing the semiconductor device 1 according to the present embodiment has the photolithography step S60 similar to that of the first embodiment. That is, the photomask 70 can be positionally aligned through positional alignment from the rear surface 10b side based on the marks (hole portions 12).

The method for manufacturing the semiconductor device 1 according to the present embodiment has the second adhering step S170 performed after the photolithography step S60, and the support substrate detaching step S180 performed after the second adhering step S170 and before the segmenting step S190. The second adhering step S170 is a step of adhering a surface on the film portion 20 side to the dicing tape 50 in a state of being supported by the support substrate 40. The support substrate detaching step S180 is a step of detaching the support substrate 40 from the base material 10. The segmenting step S190 is performed a state in which a surface on the film portion 20 side is adhered to the dicing tape 50.

In the related art, a segmenting step of cutting a film portion and a base material at the same time on a dicing tape has been performed. In the method in the related art, when the film portion is a metal film, burrs are generated from the cut portions toward the dicing tape due to the ductility of the metal. In addition, burrs of the film portion may bite into the dicing tape, making it difficult to pick up the semiconductor devices. In contrast, according to the constitutions described above, although the segmenting step S190 is performed on the dicing tape 50, since the film portion 20 has been segmented in advance, no burrs are generated from the film portion 20, and therefore the problem described above does not occur. Consequently, the semiconductor device 1 can be stably manufactured. In addition, according to this constitution, since the segmenting step S190 can be performed on the dicing tape 50, compared to when the segmenting step is performed on the support substrate 40, concern for the adhesive 30 damaging the blade 9 is eliminated.

According to at least one of the embodiments described above, by exposing the recessed portions (groove portions 11 and hole portions 12) on the rear surface 10b side to serve as marks, the base material 10 can be positionally aligned from the rear surface 10b side, and therefore it is possible to provide a method for manufacturing the semiconductor device 1 in which positional alignment of the base material 10 during steps is facilitated.

Some embodiments of the present invention have been described, but these embodiments are presented as examples and are not intended to limit the scope of the invention. These embodiments can be performed in various other forms, and various omissions, replacements, and changes can be made within a range not departing from the gist of the invention. These embodiments and modifications thereof are included in the invention described in the claims and the scope equivalent thereto as they are included in the scope and the gist of the invention.

### REFERENCE SIGNS LIST

1 Semiconductor device
10 Base material
10a Device surface
10b Rear surface (grinding surface)
11, 11A Groove portion (recessed portion, mark)
12 Hole portion (recessed portion, mark)
20 Film portion
40 Support substrate
50 Dicing tape
h, H Thickness
L11 Alignment line
S1 Valid division
S2 Removal division
S20 Mark forming step
S30 First adhering step
S40 Grinding step
S50 Film formation step
S60 Photolithography step (processing step)
S70 Segmenting step (processing step)
S80, S170 Second adhering step
S90, S180 Support substrate detaching step
S190 Segmenting step

1. A method for manufacturing a semiconductor device comprising:
a mark forming step of forming recessed portions on a device surface on which a circuit pattern of a base material made of a semiconductor material is formed;
a first adhering step of adhering the device surface to a support substrate;
a grinding step of forming a grinding surface by grinding a surface of the base material on a side opposite to the device surface in a state of being supported by the support substrate; and
a processing step of performing processing on the base material from the grinding surface side in a state of being supported by the support substrate,
wherein in the grinding step, the recessed portions are exposed on the grinding surface to serve as marks, and
in the processing step, the processing is performed based on the marks.

2. The method for manufacturing a semiconductor device according to claim 1,
wherein the processing step is a segmenting step of segmenting the base material by cutting the base material based on the marks in a state of being supported by the support substrate.

3. The method for manufacturing a semiconductor device according to claim 2,
wherein the device surface is provided with alignment lines dividing the base material, and
at least some of the recessed portions are groove portions overlapping the alignment lines when viewed in a thickness direction of the base material.

4. The method for manufacturing a semiconductor device according to claim 3,
wherein the base material is divided by the alignment lines into a plurality of valid divisions divided in a rectangular shape and a plurality of removal divisions disposed along an outer edge, and
the groove portions overlap parts of the alignment lines dividing the removal divisions.

5. The method for manufacturing a semiconductor device according to claim 3,
wherein the base material is divided by the alignment lines into a plurality of valid divisions divided in a rectangular shape and a plurality of removal divisions disposed along an outer edge, and
the groove portions overlap parts of the alignment lines dividing the valid divisions.

6. The method for manufacturing a semiconductor device according to claim 1 further comprising:
a film formation step, performed after the grinding step, of forming a film portion on the grinding surface,
wherein the processing step is a photolithography step of etching and removing a part of the film portion based on the marks.

7. The method for manufacturing a semiconductor device according to claim 6,
wherein the device surface is provided with alignment lines dividing the base material, and
in the photolithography step, a region in which the film portion is etched overlaps the alignment lines when viewed in a thickness direction of the base material.

8. The method for manufacturing a semiconductor device according to claim 7 further comprising:
a segmenting step, performed after the photolithography step, of segmenting the base material by cutting the base material.

9. The method for manufacturing a semiconductor device according to claim 8 further comprising:
a second adhering step, performed after the photolithography step, of adhering a surface on the film portion side to a dicing tape in a state of being supported by the support substrate; and
a support substrate detaching step, performed after the second adhering step and before the segmenting step, of detaching the support substrate from the base material,
wherein the segmenting step is performed a state in which the surface on the film portion side is adhered to the dicing tape.
